(19) United States
(12) Patent Application Publication
(10) Pub. No.: US 2025/0355028 A1
(43) Pub. Date: Nov. 20, 2025

(54) 3D QUANTUM FIELD DETECTOR

(71) Applicant: Quantum Cognition Corporation, Edgewood, NM (US)

(72) Inventor: Scott A. Wilber, Edgewood, NM (US)

(21) Appl. No.: 19/210,150

(22) Filed: May 16, 2025

Related U.S. Application Data
(60) Provisional application No. 63/649,904, filed on May 20, 2024.

(51) Int. Cl. G01R 27/26

(52) U.S. Cl. CPC G01R 27/2605

(57) ABSTRACT

A detector can include a group of orthogonally oriented quantum detectors, wherein each quantum detector among the group of orthogonally oriented quantum detectors can detect variations in a quantum field. The detector can further include a signal processor that can determine a direction and magnitude of the detected quantum field variations based on outputs from the group of orthogonally oriented quantum detectors. Each quantum detector among the group of orthogonally oriented quantum detectors can include an array of Zener diodes biased to produce shot noise modulated by quantum field variations. The detector can constitute a three-dimensional quantum field detector. In some embodiments, a tunneling sensor comprising a tunneling capacitor may be implemented in place of Zener diode.

### CROSS REFERENCE TO PATENT APPLICATION

This patent application claims priority to U.S. Provisional Patent Application Ser. No. 63/649,904, entitled “3D Quantum Field Detector,” which was filed on May 20, 2024, and is incorporated herein by reference in its entirety.

### TECHNICAL FIELD

Embodiments are related to the field of information technology.

Embodiments further relate to quantum field detectors. Embodiments also relate to devices, systems, and signal processing methods for detecting disturbances or variations in the ambient quantum field and determining the direction of the source of these variations relative to a measurement point and providing information from and/or about the source.

### BACKGROUND

Quantum sensors have traditionally relied on “quantum resources” to measure changes at the atomic level. These quantum resources encompass physical qualities that are not present in classical physics, such as entanglement, superposition and coherence. These phenomena allow quantum sensors to achieve levels of sensitivity and precision unattainable by classical sensors.

Despite these advantages, previous quantum sensors have been constrained to measuring classical properties or forces, including gravity, magnetic fields and electromagnetic radiation. For instance, atomic clocks use quantum entanglement to achieve highly accurate timekeeping, and SQUIDs (Superconducting Quantum Interference Devices) exploit quantum interference to detect extremely weak magnetic fields. However, these sensors are often complex, require cryogenic temperatures, and are limited to detecting classical properties.

Furthermore, the existing quantum sensors do not typically provide direct information about non-classical (quantum mechanical) properties of the sources they measure. Instead, they infer quantum phenomena indirectly through classical effects. This limitation restricts their application in fields where direct detection and analysis of quantum mechanical properties are crucial.

### BRIEF SUMMARY

The following summary is provided to facilitate an understanding of some of the innovative features unique to the disclosed embodiments and is not intended to be a full description. A full appreciation of the various aspects of the embodiments disclosed herein can be gained by taking the entire specification, claims, drawings, and abstract as a whole.

It is, therefore, an aspect of the embodiments to provide for an improved quantum sensor.

It is also an aspect of the embodiments to provide for a 3D quantum field detector including systems, devices and signal processing methods, which can be configured to detect disturbances or variations in the ambient quantum field and to determine the direction of the source of these variations relative to the measurement point, providing information from and/or about the source.

It is another aspect of the embodiments to provide for a detection system that can “witness” quantum entanglement (note: quantum entanglement witness is a term in quantum mechanics that relates to the measurement of properties revealing entanglement between two systems without collapsing their wavefunction).

The aforementioned aspects and other objectives and advantages can now be achieved as described herein.

In an embodiment, a detector can be implemented, which can include a plurality of orthogonally oriented quantum detectors, wherein each quantum detector among the plurality of orthogonally oriented quantum detectors can detect variations in a quantum field, and a signal processor that can determine a direction and magnitude of the detected quantum field variations based on outputs from the plurality of orthogonally oriented quantum detectors.

In an embodiment, each quantum detector among the plurality of orthogonally oriented quantum detectors can include an array of Zener diodes biased to produce shot noise modulated by quantum field variations.

In an embodiment, each quantum detector can include an integrated capacitor having a leakage current, largely due to tunneling, responsive to variations in the quantum field.

In an embodiment, the quantum detectors among the plurality of orthogonally oriented quantum detectors can be aligned along orthogonal geographic axes, with one quantum detector aligned along a Y axis pointing true north and another quantum aligned along a Z axis pointing vertically toward the zenith.

In an embodiment, the signal processor can be configured to perform multiple measurements and apply signal averaging or other techniques to improve a signal-to-noise ratio.

In an embodiment, the detector can comprise a three-dimensional quantum field detector (QFD3D detector).

In an embodiment, a three-dimensional quantum field detector can be implemented, which can include: a first quantum detector aligned along a first axis; a second quantum detector aligned orthogonally to the first quantum detector along a second axis; a third quantum detector aligned orthogonally to the first and second quantum detectors along a third axis, wherein the first, second, and third quantum detectors are respectively aligned with a geographic X-Y-Z coordinate system such that the Y axis is oriented toward geographic true north, and the Z axis is oriented vertically toward the zenith, wherein each quantum detector comprises an array of Zener diodes biased to produce tunneling currents that generate shot noise signals; and a signal processor configured to receive and process output signals from the arrays of Zener diodes in each of the three quantum detectors, wherein variations in a quantum field modulate the tunneling current in the Zener diode arrays, and wherein the signal processor performs multiple measurements and enhances a signal-to-noise ratio to determine a magnitude and a direction of the detected quantum field variation in three-dimensional space.

In an embodiment, a method for measuring classical changes due to non-classical, i.e., quantum mechanical influences, can involve: detecting quantum field disturbances using a device comprising an array of quantum sensors; amplifying the detected signal using a low-noise instrumentation amplifier; filtering the amplified signal using a low-pass filter to prevent aliasing; and digitizing the filtered signal using an analog-to-digital converter (ADC).

An embodiment of the method can involve determining a direction of quantum mechanical influences relative to the orientation of the device using sensors oriented to orthogonal axes.

In an embodiment of the method, the device can be a three-dimensional quantum field detector.

### BRIEF DESCRIPTION OF THE DRAWINGS

The accompanying figures, in which like reference numerals refer to identical or functionally-similar elements throughout the separate views and which are incorporated in and form a part of the specification, further illustrate the present invention and, together with the detailed description of the invention, serve to explain the principles of the present invention.

FIG. 1 illustrates a schematic diagram depicting the sandwich structure of a Zener diode, which can be adapted for use with an embodiment;

FIG. 2 illustrates a diagram depicting an example of the tunneling current normalized to show only the effect of the angle of incidence on the detector;

FIG. 3 illustrates a block diagram depicting the components of a QFD3D device including a group of sensor elements responsive to changes in the quantum field and producing modulations in current flow, in accordance with an embodiment;

FIG. 4 illustrates the orthogonal physical configuration of the X, Y, and Z sensing elements on a printed circuit board, in accordance with an embodiment;

FIG. 5 illustrates a schematic diagram depicting the front end of the QFD3D device including a preamplifier, a low-pass filter and a bias subtractor, in accordance with an embodiment;

FIG. 6 illustrates a graph depicting an example of a typical result of averaging a large number of Fast Fourier Transforms (FFTs) of one of the signal outputs, in accordance with an embodiment;

FIG. 7 illustrates a partial schematic diagram of multiple sensor elements feeding their combined signals into a single amplifier, in accordance with an embodiment;

FIG. 8 illustrates a flow chart depicting logical operational steps of a method for measuring classical changes due to non-classical, i.e., quantum mechanical influences, in accordance with an embodiment;

FIG. 9 illustrates a flow chart depicting logical operational steps of a method for measuring classical changes due to non-classical, i.e., quantum mechanical influences including determining a direction of quantum mechanical influences relative to the orientation of the device using sensors oriented in orthogonal axes, in accordance with an embodiment;

FIG. 10 illustrates a flow chart depicting logical operational steps of a method for increasing the signal-to-noise ratio (SNR) of a detected quantum mechanical influence, in accordance with an embodiment;

FIG. 11 illustrates a flow chart depicting logical operational steps of a method for synchronizing the signal sampling of widely separated devices using a GPS receiver, in accordance with an embodiment;

FIG. 12 illustrates a flow chart depicting logical operational steps of a method for analyzing quantum mechanical influences using artificial intelligence (AI) algorithms, in accordance with an embodiment;

FIG. 13 illustrates a flow chart depicting logical operational steps of a method for observing patterns in brain activity using a QFD3D device, in accordance with an embodiment;

FIG. 14 illustrates a flow chart depicting logical operational steps of a method for detecting control signals using a QFD3D device; and

FIG. 15 illustrates a schematic diagram depicting a tunneling sensor, which can be implemented in accordance with an embodiment.

Like reference numerals utilized herein can refer to identical or similar parts or elements.

### DETAILED DESCRIPTION

The particular values and configurations discussed in these non-limiting examples can be varied and are cited merely to illustrate one or more embodiments and are not intended to limit the scope thereof.

Subject matter will now be described more fully hereinafter with reference to the accompanying drawings, which form a part hereof, and which show, by way of illustration, specific example embodiments. Subject matter may, however, be embodied in a variety of different forms and, therefore, covered or claimed subject matter is intended to be construed as not being limited to any example embodiments set forth herein; example embodiments are provided merely to be illustrative. Likewise, a reasonably broad scope for claimed or covered subject matter is intended. Among other things, for example, subject matter may be embodied as methods, devices, components, or systems. Accordingly, embodiments may, for example, take the form of hardware, software, firmware, or any combination thereof (other than software per se). The following detailed description is, therefore, not intended to be interpreted in a limiting sense.

Throughout the specification and claims, terms may have nuanced meanings suggested or implied in context beyond an explicitly stated meaning. Likewise, phrases such as “in one embodiment” or “in an example embodiment” and variations thereof as utilized herein do not necessarily refer to the same embodiment and the phrase “in another embodiment” or “in another example embodiment” and variations thereof as utilized herein may or may not necessarily refer to a different embodiment. It is intended, for example, that claimed subject matter include combinations of example embodiments in whole or in part.

In general, terminology may be understood, at least in part, from usage in context. For example, terms such as “and,” “or,” or “and/or” as used herein may include a variety of meanings that may depend, at least in part, upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein, depending at least in part upon context, may be used to describe any feature, structure, or characteristic in a singular sense or may be used to describe combinations of features, structures, or characteristics in a plural sense. Similarly, terms such as “a,” “an,” or “the”, again, may be understood to convey a singular usage or to convey a plural usage, depending at least in part upon context.

In addition, the term “based on” may be understood as not necessarily intended to convey an exclusive set of factors and may, instead, allow for existence of additional factors not necessarily expressly described, again, depending at least in part on context. Furthermore, the phrase “at least one” may be understood to convey the meaning “one or more”. For example, “at least one widget” may convey the concept of “one or more widgets”.

The following definitions are provided:

Analog-to-Digital Converter (ADC): A device that converts continuous analog signals into discrete digital numbers, enabling the processing and analysis of the signals by digital systems.

Artificial Intelligence (AI) Algorithms: Computational methods and techniques that enable machines to learn from data, recognize patterns, and make decisions or predictions based on the analysis of the data.

Bias Current: The direct current that flows through a device, such as a Zener diode, to set its operating point and enable its proper function.

Entanglement: A quantum mechanical phenomenon where the quantum states of two or more particles become inseparable, such that the measured state of one particle instantly reveals the state of the other, regardless of the distance between them.

Environmental Monitoring: The use of devices and techniques to observe and measure environmental conditions, such as changes in climate, air quality, water quality, and geological activity.

Fusion Processes: Nuclear reactions where two atomic nuclei combine to form a heavier nucleus, releasing energy. In the context of the sun, these are quantum-based processes that power the sun.

Low-Pass Filter: An electronic filter that allows signals with a frequency lower than a certain cutoff frequency to pass through and attenuates signals with frequencies higher than the cutoff frequency.

Medical Diagnostics: The process of determining the nature of a disease or condition by examining and analyzing patient data, often involving the use of specialized devices and technologies.

Non-Classical Influences: Effects or disturbances that cannot be explained by classical physics and are instead described by quantum mechanics, including phenomena such as entanglement, superposition, and quantum tunneling.

One Pulse Per Second (1PPS): A precise timing signal provided by GPS receivers, used to synchronize clocks and oscillators to the start of each second.

1 nanometer (nm) is 1×10⁻⁹ meters. 1000 nm=1 micrometer (μm, 1×10⁻⁶ meters).

Oscillator: An electronic circuit that produces a periodic oscillating signal, often used to provide a stable time base for timing and synchronization purposes.

Quantum-Based Processes: Processes that occur due to the fundamental principles of quantum mechanics, often involving subatomic particles and phenomena that do not have classical analogs.

Quantum Field: A fundamental entity in quantum field theory, representing a field that permeates space and can manifest as particles and waves. Quantum fields are the underlying structures from which particles such as electrons and photons arise, and they are responsible for mediating fundamental forces in nature.

Quantum Field Disturbances: Variations or fluctuations in the quantum field that can affect the behavior of particles and systems at the quantum level.

Quantum Mechanical Influences: Effects on physical systems that arise due to the principles of quantum mechanics, including but not limited to quantum field disturbances, entanglement, and tunneling effects.

Quantum Sensor or Quantum Detector: A sensor or detector whose operation is based on quantum mechanical principles, capable of detecting and measuring disturbances or variations in quantum fields.

Root Mean Square (RMS): A statistical measure of the magnitude of a varying quantity, often used in physics and engineering to quantify the average power of an oscillating signal.

Shot Noise: A type of electronic noise that occurs when electrons or other charge carriers pass (tunnel) through a barrier, resulting in a random fluctuation in the current. It is a fundamental quantum mechanical effect.

Spacelike Separation: A condition in which two events are separated by such a distance that no signal or information can travel between them at or below the speed of light during the interval between the events.

Tunneling Current: The flow of charge carriers through a barrier in a quantum tunneling process, which occurs due to the wave-like properties of particles as described by quantum mechanics.

Witnessing Entanglement: The process of measuring properties that reveal entanglement between two systems without collapsing their wavefunction, thereby confirming their interconnected quantum states.

The embodiments relate to a 3-Dimensional Quantum Field Detector (QFD3D) that can detect variations in the quantum field and can determine the direction of these variations. The device can include three orthogonally oriented quantum detectors or sensors; each composed of arrays of Zener diodes biased to produce shot noise. These detectors or sensors can be aligned with geographic directions, with the Y axis pointing true north and the Z axis pointing vertically toward the zenith. Variations in the quantum field modulate the tunneling current through the detectors. Multiple measurements and signal processing can increase the signal-to-noise ratio, providing the magnitude and direction of the detected signals.

The disclosed 3-dimensional quantum field detector addresses the previously identified problems and limitations associated with conventional quantum sensors. Using a straightforward construction and capable of operating at room temperature, the QFD3D (or QFD3D device/sensor/detector) can directly measure non-classical influences. By utilizing arrays of Zener diodes biased to produce shot noise, the QFD3D can detect variations in the quantum field and determine the direction of these variations relative to the measurement point. This innovative approach opens new avenues for applications that require direct interaction with quantum phenomena, such as advanced scientific research, environmental monitoring and novel communication technologies. Note that the terms “sensor” and “detector” as utilized herein can be utilized interchangeably with one another to refer to the same device or component.

The QFD3D's design not only simplifies the construction and operation of quantum sensors but also enhances their functionality by providing information about the quantum mechanical properties of the sources of quantum fields. This advancement represents a significant step forward in the development of practical, high-performance quantum sensors for a wide range of applications.

To effectively respond to quantum mechanical influences, the sensor element's operation must be based on quantum principles. A prime example of such an element is a Zener diode junction. When appropriately designed and biased, a Zener junction produces a substantial amount of shot noise through quantum tunneling. Variations in the ambient quantum field can modulate the tunneling current, which is monitored by the detector. These variations can be caused by influences such as a test subject's mental activity or by more universal or even astronomical sources.

Directionality in the detector is achieved through its physical design, which incorporates three separate sensors oriented to primarily detect X, Y, and Z Cartesian components. In a typical miniature glass-encapsulated Zener diode, the active element consists of a semiconductor sandwich structure with a thin junction layer, usually less than 1-micrometer (μm), down to tens of nanometers (nm) thick. The tunneling current is highly dependent on the thickness of the junction, resulting in maximum current flow in the direction orthogonal to the plane of the junction. Other devices, such as tunnel diodes and specially designed integrated capacitors, may also exhibit these properties.

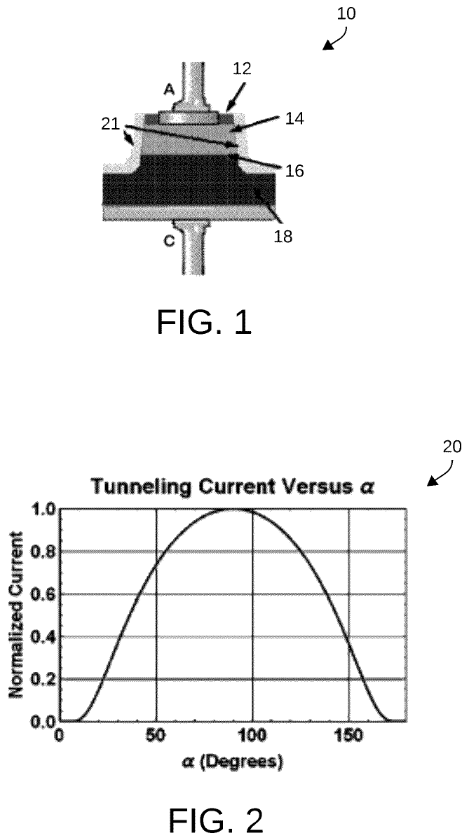

FIG. 1 illustrates a schematic diagram depicting the sandwich structure of a Zener diode 10, which can be adapted for use with an embodiment. The Zener diode 10 shown in FIG. 1 can include a silicon oxide insulating layer 12 located above a heavily doped P+ type layer 14, which in turn is located above a very thin junction layer 16. A heavily doped N+ type layer 18 can be disposed below the thin junction layer 16. A glass passivation layer(s) 21 are also shown in FIG. 1 located generally on the extremities or sides of the Zener diode 10.

The active area where tunneling occurs is across the junction layer 16. Geometrically, the distance a charge carrier must cross is r,

$$r = \frac{y}{sin α} ,$$

where r is the distance, y is the thickness (in this case, the junction thickness) and a is the angle between the plane of the junction and the direction of r.

The tunneling current, Iₜ, is approximated by Simmons' formula:

$${I}_{t} \approx A {e}^{- 2 κ d}$$

where, Iₜ is the tunneling current, A is a factor that depends on the specific properties of the device and the material, d is the thickness of the tunneling barrier, and K is the tunneling attenuation factor, related to the effective mass of the charge carriers and the shape of the potential barrier.

This approximation shows that tunneling current decreases exponentially with increasing thickness, d. Iₜ should be appreciated that the configuration shown in FIG. 1 of the Zener diode 10 is presented for illustrative and exemplar purposes only and is not a limiting feature of the embodiments.

FIG. 2 illustrates a graph 20 depicting data indicative of an example of the tunneling current normalized to show only the effect of the angle, a, on Iₜ. This dependence on tunneling distance is the basis for directional measurements. A sensor's precise directional properties depend on its specific design: materials, doping and dimensions. Iₜ is difficult to obtain an accurate model from first principles, so measurements on the actual detector are used to estimate unknown variables.

While the directional properties are significant, each of the X, Y, and Z sensors may have some overlapping signal amplitude from the other sensors. This overlap necessitates a method to accurately decompose the signals into their respective X-, Y-, and Z-directed vectors. Such decomposition can be accomplished by iterative analysis using simultaneous equations.

The process begins with an initial estimation of the direction of incidence based on the uncorrected outputs from the X, Y, and Z sensors. This initial direction is used to estimate the contribution of each sensor's signal to the overall detected signals. In this context, the total detected signal in each sensor is considered to be a combination of the contributions from all three axes.

Mathematically, this involves setting up three simultaneous equations representing the observed signals in terms of the unknown contributions from each axis. The general form of these equations is:

$${S}_{x} = {C}_{xx} X + {C}_{xy} Y + {C}_{xz} Z$$

$${S}_{y} = {C}_{yx} X + {C}_{yy} Y + {C}_{yz} Z$$

$${S}_{z} = {C}_{zx} X + {C}_{zy} Y + {C}_{zz} Z$$

Where Sₓ, S_{y} and S_{z} are the observed signals in the X, Y, and Z sensors, and Cᵢⱼ are the coefficients representing the contribution of the j-th axis to the i-th sensor.

These equations are solved to obtain a first-order correction, providing an initial separation of the contributions from each axis. This correction is then applied to refine the estimates of the signals' contributions, and the process is repeated iteratively.

With each iteration, the corrections become smaller as the estimated direction of incidence becomes more accurate. The iteration continues until the changes in the estimated values fall below a predefined convergence threshold, indicating that the process has achieved a stable solution.

This iterative refinement ensures that the final directional values are precise, accounting for the initial overlapping signals and providing a clear decomposition into the X-, Y-, and Z-directed components. This method enhances the accuracy of the disclosed QFD3D device in determining the direction of quantum field disturbances, enabling more reliable and detailed measurements.

The disclosed QFD3D device can be used for receiving both information and control signals. Unlike conventional approaches, this invention does not rely on direct physical or electrical contact or the use of electromagnetic fields for signal communication. A notable application of this technology includes the integration of artificial intelligence (AI) for the purpose of analyzing signal patterns detected by the device. This Al-enabled feature allows the non-invasive interpretation of a user's thoughts or patterns or neural activations based on patterns in the signals.

Current technology for performing a comparable task include interpreting signals from Magnetic Resonance Imaging (MRI) of the brain, or from sensor wires implanted directly in the brain. These approaches have significant limitations preventing common usage. That is, they are highly complex, expensive and too large (for MRI), or they present significant risks to the subject or patient (for implanted devices). Other approaches, known as “Brain-Machine Interfaces,” use an array of electrodes applied to the head or scalp to attempt to observe internal electronic signals from neuronal firings. These devices are highly limited in the signals they can acquire due to significant capacitance and conductivity in brain tissue, causing many signals from large volumes of the brain to become inseparable when detected by surface electrodes.

Finally, a Magneto-Encephalograph (MEG) tries to detect magnetic fields produced by currents associated with neuronal firings. This requires an array of Superconducting Quantum Interference Device (SQID) magnetometers to detect the miniscule fields involved. Beside the cryogenic temperature required by the SQUIDs and the prohibitive cost, the subject is typically required to be measured in a magnetically shielded enclosure, which is highly impractical for common usage.

A number of different sensor elements are possible. In modern integrated circuits, where the dimensions are measured in nanometers (nm), a capacitor comprising two flat metal layers separated by a very thin insulator, composed for example of aluminum oxide (Al₂O₃), will provide a tunneling component of the desired type. Normally, leakage in ICs is minimized by design, but it can also be increased-by making the insulation layer extremely thin, less than 1 μm, but down to nanometers. The dielectric constant, ε, of the insulator should be relatively low, since the capacitance is directly proportional to dielectric constant and the area of the conductor sheet. Larger capacitance would lower the frequency response of the sensor, which is generally undesirable. Low dielectric material (relative to silica, SiO₂, with ε=3.9) used in semiconductors can have & in the range of 1.5-2.5. Aluminum oxide has a higher ε up to about 9-still relatively low-and it is easy to use and inexpensive in standard integrated circuits.

### Precise Timing by GPS Time

Many applications may require widely separated QFD3D devices to provide signals that are sampled at precisely the same time, within a small tolerance ranging from about 10 to 100 nanoseconds (ns). This precise timing is especially important for astronomical observations or events that have wide-spread effects or that affect many people. Iₜ also facilitates certain scientific experiments where spacelike separation (sufficiently far apart so no signal can pass between at the speed of light during a measurement) is essential, such as detecting or “witnessing” entanglement.

A GPS receiver provides both the precise location and a time signal that is typically one pulse per second (1PPS), with a transition that is exactly at the beginning of each second. The 1PPS signal is used to control or discipline (synchronize) an oscillator to provide signal sampling at exactly specified times, within the tolerance of the GPS system. To facilitate getting and maintaining a GPS fix (a lock on enough GPS satellites to calculate location and time), the GPS receiver should be of a newer type, such as 8^{th}, 9^{th} or 10^{th} generation, used with a good active antenna.

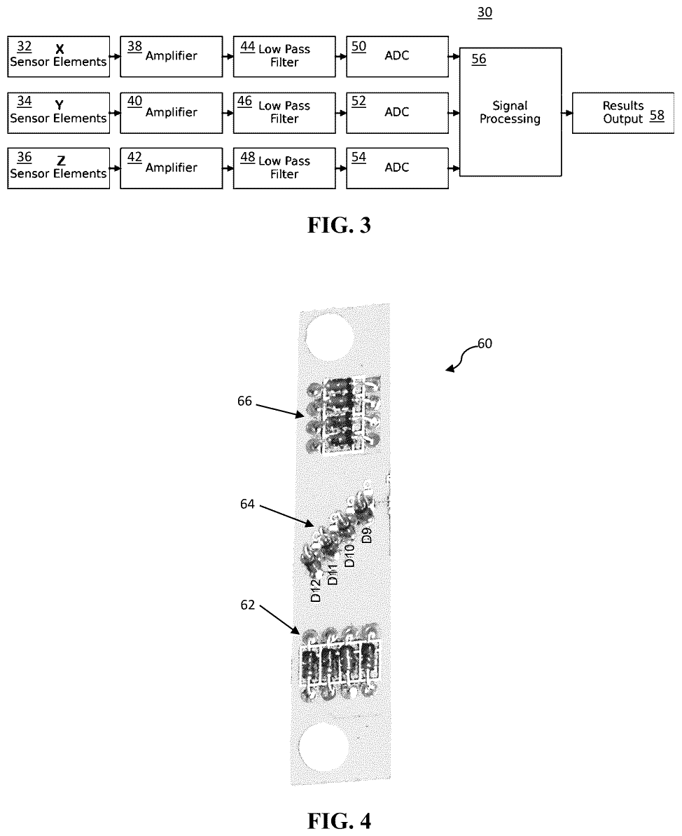

FIG. 3 illustrates a block diagram depicting the components of a QFD3D device 30 including a group of sensor elements 32, 34, 36 responsive to changes in the quantum field and producing modulations in current flow, in accordance with an embodiment. These modulations are converted to voltage signals that are amplified respectively via amplifiers 38, 40, 42 to convenient levels. The signals are then passed through respective low-pass filters 44, 46, 48 to prevent aliasing in the subsequent digitized form. The filtered signals are digitized by respective analog-to-digital converters (ADCs) 50, 52, 54. The digitized signals can be sent, in some embodiments via USB or other forms of electronic communications, to a computer for signal processing via a signal processor 56. The processed results are output 58 in a chosen form for use. Note that the term “QFD3D device” as utilized herein can be utilized interchangeably with the term “quantum detector” or “QFD3D detector” to refer to the same device, apparatus or system.

Note that the term “signal processor” as utilized herein can relate to any combination of hardware, software, or firmware, or a system thereof, that is configured to receive, manipulate, analyze, condition, or interpret electrical signals or data streams derived from one or more sensors or detectors. A signal processor may include, for example, analog or digital components, microprocessors, digital signal processors (DSPs), field-programmable gate arrays (FPGAs), application-specific integrated circuits (ASICs), general-purpose computing devices, or any other circuitry capable of performing arithmetic, logical, statistical, or computational operations on input signals to extract relevant information, enhance signal quality, or facilitate decision-making or control operations.

FIG. 4 illustrates a diagram depicting the orthogonal physical configuration of respective X (top), Y (bottom) and Z (center) sensing elements 66, 62, 64 on a printed circuit board (PCB) 60, in accordance with an embodiment. Note that in the example configuration shown in FIG. 4, the Z sensors (i.e., Z sensing elements 64) can be mounted upright (vertically) on the PCB. The signals produced by the sensor elements 66, 62, 64 are extremely small, on the order of nanovolts per root Hertz (nV/VHz), so careful design can be required to prevent unwanted noise signals.

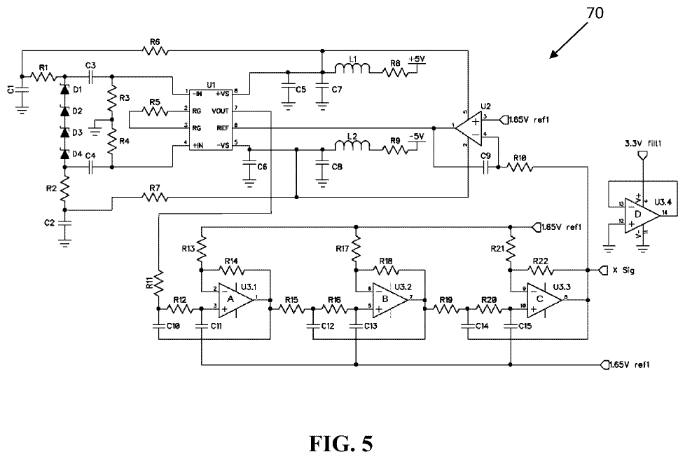

FIG. 5 illustrates a schematic circuit diagram depicting the amplifier section 70 of the QFD3D device 30, in accordance with an embodiment. That is, the amplifier section 70 shown in FIG. 5 can implement the amplifiers 38, 40, 42 shown in FIG. 3. Note that in the example embodiment shown in FIG. 5, Zener diodes D1-D4 (e.g., 1N4615, Central Semiconductor Corporation) can be constitute the sensor elements. U1 is a low-noise instrumentation amplifier (e.g., AD8421ARMZ, Analog Devices), U2 (e.g., TLV9151QDBVRQ1, Texas Instruments) is an integrator that subtracts any bias from the amplified, filtered signal. U3 (e.g., OPA4325IPW, Texas Instruments) can comprise, for example, a 1 kHz, 6^{th order Butterworth low-pass filter. I}ₜ should be appreciated that reference to such specific devices and components is for illustrative and exemplary purposes only and should not be considered limiting features of the embodiments.

A list of example passive components with respect to the configuration shown in FIG. 5 is as follows:

R1, R2; 4.99K, 0.1%, 0402: R3, R4; 1M, 0.1%, 0402: R5, 4.220, 1%, 0402 R6, R7; 59K, 1%, 0402: R8, R9; 30, 1%, 0402: R10; 133K, 1%, 0402 R11-R13, R15-R17, R19-R21; 16K, 1%, 0402 R14; 1.1K, 1%, 0402: R18; 9.31K, 1%, 0402: R22; 23.7K, 1%, 0402 C1, C2, C7, C8; 22uF, 20%, X7R, 0805: C3, C4; 0.33uF, 2%, COG, 1206 C5, C6; 0.47uF, 10%, X5R, 0402: C9; 4.7uF, 10%, X7R, 0603 C10-C15; 0.01uF, 10%, X7R, 0402

R6 and C1, and R7 and C2 provide filtered bias voltages to the sensor elements. Current variations in the sensor elements, D1-D4, are converted to voltage variations across the bias resistors, R1 and R2. The voltage variations are passed through two high-pass filters, comprised of C3 and R3, and C4 and R4, having a cutoff frequency (fc) of 0.5 Hz. The signal voltage can be differentially amplified in U1, with a gain set at 2347. L1 and C7 comprise a second-order low-pass power filter for the +5 V supply.

R8 provides additional damping so the power filter is critically, or slightly over-damped. L2, C8 and R9 alikewise a power filter for the −5V supply. Capacitors C5 and C6 provide additional high-frequency filtering at the power connections of U1. U3a-U3c, and associated resistors and capacitors, is a 6^{th-order Butterworth low-pass filter with a cutoff frequency of} 995 Hz and a DC gain of 4.195. Amplifier U2, with R10 and C9 comprise an integrator that compares the X sig output to a reference voltage, 1.65V ref1. Any deviation between the average signal output and the ref voltage is subtracted by the integrator's output being sent to the ref pin of amplifier, U1. The X signal output is then sent to the input of a 12-bit ADC. The 1.65V ref is set at one-half full-scale input of the ADC, which is subtracted after conversion to restore the bipolar nature of the signal. The total voltage gain of the amplifier and the low-pass filter is Av =9,846.

### Signal Output

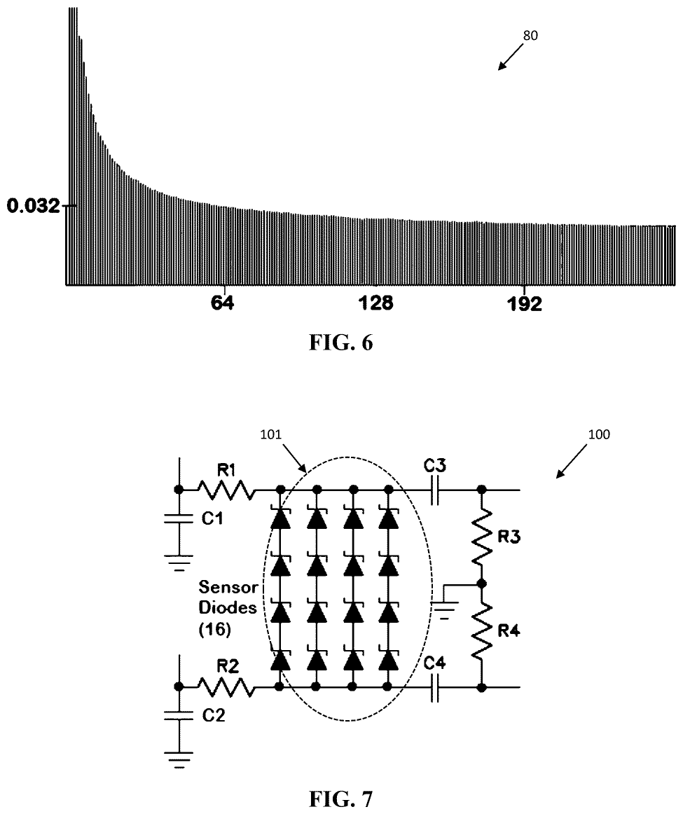

FIG. 6 illustrates a graph 80 depicting the example of a typical result of averaging a large number of Fast Fourier Transforms (FFTs) of one of the signal outputs, in accordance with an embodiment. Graph 80 shown in FIG. 6 represents frequencies from DC to 256 Hz in 1 Hz intervals, with 0.032 Vₚ₋ₚ (Volts peak-to-peak) shown as a reference amplitude. The analog signal at the input of the ADC has a peak to peak amplitude of about 90% of the full-scale input. This allows some reserve for unusual voltage excursions. Clearly there is more power at the lower frequencies, part of which is due to 1/f noise in the sensor elements. The rms (root mean square) value is calculated by dividing the peak to peak value by 2v2.

This measurement gives an average peat-to-peak output voltage of about 0.025V/VHz, which is calculated at 192 Hz to give a representation of both low-and high-frequency components. This gives an RMS voltage of 0.00884. The effective bandwidth of the 6^{th-order LP filter is} 1.0115 times the nominal fc, or 1006 Hz. The peak-to-peak signal is estimated by multiplying the RMS value at 192 Hz by the square root of the effective bandwidth and then multiplying the total RMS signal by 6, which gives a good estimate of the peak-to-peak value. The result is 1.68Vₚ₋ₚ. However, the large low-frequency components add significantly to the total amplitude at the input of the ADC, which has a full-scale range of just under 3.3V.

### Power Regulation

The power regulators can be selected for low noise and high frequency switching, which is easier to filter out. In addition to using all low-noise and low offset amplifiers, all sensitive sections have separate filtering on their power supplies. Digital and analog section are kept separate as much as possible. Digital and analog power is separately filtered and the digital interface and power section are shielded. Noisy digital or control lines are kept far from low-level analog sections, which are at opposite ends of the PCB.

### Signal Processing

To understand the signal processing approaches, it is necessary to understand the nature of the signal produced by the sensor elements. The Zener diodes in this embodiment are biased to pass about 30 μA (microamps) of average current. The resulting signal comprises two main components: a large amplitude random shot noise component and a small quantum-field-induced modulation of the tunneling current, which is coherent across sensors and over some period of time during which it is stationary. At any time, the signal from each sensor is represented by, Signal=N+S, where N is the random noise component and S is the coherent signal component of interest.

The simplest way to increase the signal-to-noise ratio (SNR) in this type of signal is to average a number of independent samples during which the signal component is relatively constant. The SNR increases approximately with the square root of the number of samples (n) used in the average. That is, if 100 noisy samples are averaged, the SNR in the averaged signal will increase by a factor of 10. This is because the random noise component, N, increases as N\sqrt{n}, while the coherent component increases by S·n. Therefore, SNR (n) is

$$\frac{S \cdot n}{N \sqrt{n}} = \frac{S}{N} \sqrt{n} .$$

This approach has the advantage of being very simple, but a disadvantage that it takes a large n to achieve a significant SNR when it is initially very low. Therefore, it is desirable to have a design that can be easily implemented in a custom integrated circuit, in which hundreds or even thousands of sensors operate simultaneously. To help in this regard, arrays of sensors can be used with outputs going to a single amplifier. Such implementations in custom ICs greatly increase the feasibility for practical applications where small size and low cost are crucial.

FIG. 7 illustrates a schematic diagram depicting a partial view of a circuit 100 including the sensors from FIG. 5, illustrating an embodiment wherein multiple sensor elements feed their combined signals into a single amplifier. In the configuration of circuit 100, a bias resistor R1 can connect electronically to a capacitor C1, which in turn connects to ground. A bias resistor R2 can connect electronically to capacitor C2, which in turn also connects to ground. A group of sensor diodes 101 is also depicted in FIG. 7 as part of the circuit 100. The group of diodes 101 connect electronically to resistor R2 and resistor R1 and also connect to a capacitor C3 and a capacitor C4. The capacitor C3 is connected electronically to a resistor R3 and the capacitor C4 is connected electronically to a resistor R4, each of these acting as high-pass filters. The resistors R3 and R4 connect electronically to one another also to ground. Each diode in the group of diodes 101 may be a Zener diode such as the Zener diode 10 shown in FIG. 1.

In the embodiment shown in FIG. 7, resistors R6 and R7 of FIG. 5 can be adjusted (e.g., reduced) so that the current through each of the four series diode circuits of the group of sensor diodes 101 is approximately the same as the current through the single series circuit of FIG. 5 (D1-D4). If the bias current for one series circuit is 30 μA, the total bias current is then 120 μA.

By measurement, the Zener voltage (V_{z}) is about 1.4V at 30 μA, making the total voltage drop for 4 series diodes 5.6V. R1 and R2 are 4.99K, and their total voltage drop is 1.1976V at 120 μA. Combined with the total V_{z}, this gives 6.7976V. Assuming a nominal 10.0V between the positive and negative supplies, this leaves 3.2024V to be dropped across both R6 and R7, or 1.6012V each. The adjusted (reduced) values for each is 1.6012V/120 μA=13.34K. The closest nominal 1% resistor value is 13.3K.

Whatever approach is used to increase the signal-to-noise, the resulting X, Y and Z signals can be further processed to determine the direction relative to the orientation of the QFD3D device 30. To obtain meaningful direction information, the sensor elements can be oriented with respect to the PCB axes, the X axis being set parallel with the long direction of the PCB. Then the PCB can be oriented with the Y axis pointing toward true north and the board leveled so the Z axis is vertical with respect to the PCB and the Earth's surface. This orientation can be achieved using a compass and a simple bubble level. A slight complication may involve the adjustment for the declination, or the angle between magnetic north, which can be measured with the compass, and true north. This angle varies with location and also changes slowly over time.

Directional information may not be important in some applications. If only the presence and polarity of changes in the quantum field are of interest, different sensing elements can be used. For example, a reverse-biased emitter-base junction in a bipolar junction transistor (BJT) produces shot noise like a Zener junction. Certain types of high-frequency transistors, such Silicon-Germanium NPN, capable of GHz frequencies, have very low emitter base breakdown voltage (VEBO), i.e., less than 1 Volt. At low current, in the range of a few microamps to tens of microamps, the breakdown voltage is only a few tenths of a Volt.

Note that in some embodiments, 16-25 of these transistor emitter-base junctions may be connected in series and used in place of the 4 Zener diodes of FIG. 5. An array of these, connected as shown in the example of FIG. 7, can contain up to about 100 sensor junctions in a very small area. Iₜ is important to note that a significant current flowing in reverse through the emitter-base junction will eventually damage the junction. This may happen partly due to the long-term buildup of “hot carriers.” Hot carriers are charge carriers (typically electrons) that are highly accelerated by the electric fields in the transistor's channel. These carriers can gain enough energy to become embedded in the surrounding oxide insulation, creating trapped charges. The accumulation of these trapped charges creates a space charge region that interferes with the normal flow of current, ultimately reducing the efficiency and reliability of the junction.

The physical construction of these high-frequency transistors may allow for some directional dependence, but the junction area versus thickness is not as favorable in that respect as the Zener diode structure previously described.

The applications of the QFD3D device 30 are vast and diverse, spanning multiple scientific, industrial and technological fields. One possible application can involve artificial intelligence (AI) integration. For example, by integrating with Al algorithms, the QFD3D device 30 can be used to analyze complex signal patterns for various applications. This includes enhancing machine learning models by providing additional quantum data inputs, improving the accuracy and capabilities of Al systems.

The QFD3D device 30 can also be used in astronomical observations to detect and analyze quantum disturbances from distant cosmic events. Its precise timing capabilities allow for synchronization of data from multiple devices located in different parts of the world, providing a comprehensive view of celestial phenomena.

In addition, the QFD3D device 30 can be applied in developing advanced communication systems that leverage quantum field variations for transmitting and receiving information. This could lead to more secure and efficient communication methods.

In addition, the QFD3D device 30 can be used to monitor environmental changes by detecting subtle quantum field variations that might correlate with specific environmental conditions or changes. This could be valuable in fields such as geology, meteorology, and oceanography.

In some embodiments, QFD3D devices can be integrated into advanced medical diagnostic tools to non-invasively detect and analyze quantum field disturbances that might correlate with physiological processes. This could lead to new diagnostic techniques and enhance the understanding of various medical conditions.

Another important application for the QFD3D device 30 can involve observation of brain activity patterns. For example, information regarding neuronal activity can be decoded using Al algorithms to interpret the signals from one, or an array of QFD3D devices. One or more QFD3D devices can be placed in proximity to a subject's head. This placement should be consistent during training and use. Initially, a large database of signals can be acquired for training the Al. The subject can be then asked to think a particular thought, which can include an image, sound, smell, feeling or taste. Each repetition of these thoughts, or visualizations, can be synchronized with the data collection. The patterns the Al recognizes may be unique to each individual, though there will likely be some common patterns among subjects. Specific information, such as control commands, enables hands-free control of a wide variety of devices and applications.

The QFD3D device 30 is ideal for scientific experiments that require precise measurement and analysis of quantum field disturbances. This includes experiments in quantum mechanics, such as observing entanglement or other quantum phenomena, where spacelike separation is crucial. The device may also be adapted for use in security and surveillance applications to detect unauthorized or suspicious activities through their quantum field signatures. This application can enhance the effectiveness of security systems by providing an additional layer of detection.

The QFD3D device 30 can also observe subtle changes in fusion or other quantum-based processes in the sun. This may allow earlier and more accurate prediction of solar storms and other event that can affect us, especially satellites and other high technology.

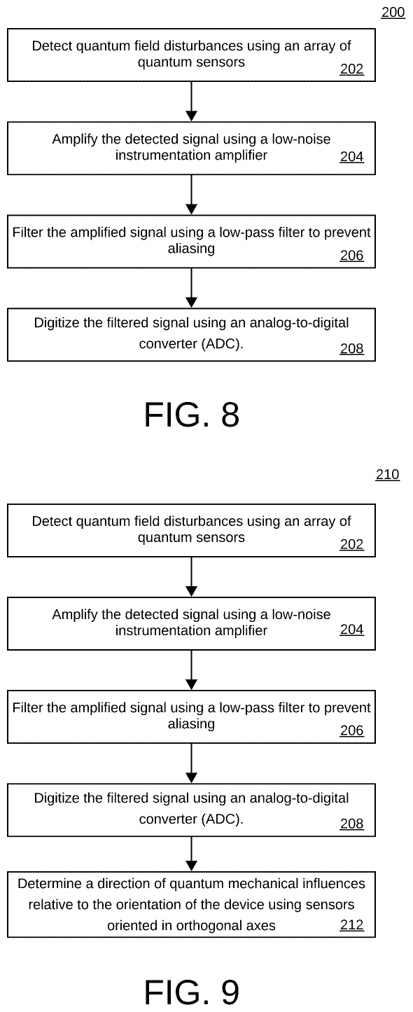

FIG. 8 illustrates a flow chart depicting logical operational steps of a method 200 for measuring classical changes due to non-classical, i.e., quantum mechanical influences, in accordance with an embodiment. As shown at block 202, a step or operation can be implemented to detect quantum field disturbances using a device comprising an array of quantum sensors. Next, as depicted at block 204, a step or operation can be implemented to amplify the detected signal using a low-noise instrumentation amplifier such as, for example, the amplifiers 38, 40, 42 shown in FIG. 5. Thereafter, as shown at block 206, a step or operation can be implemented to filter the amplified signal using a low-pass filter to prevent aliasing. Then, as illustrated at block 208, a step or operation can be implemented to digitize the filtered signal using an analog-to-digital converter (ADC) such as, for example, analog-to-digital converters ADC 50, 52, 54 shown in FIG. 3.

FIG. 9 illustrates a flow chart depicting logical operational steps of a method 210 for measuring classical changes due to non-classical, i.e., quantum mechanical influences including determining a direction of quantum mechanical influences relative to the orientation of the QFD3D device 30 using sensors oriented in orthogonal axes, in accordance with an embodiment. The method 210 shown in FIG. 8 includes the various operations such as those of block 202, 204, 206, 208 shown in FIG. 8. In the interest of brevity, these steps or operations will not be repeated. The method 210 includes an additional step or operation, as shown at block 212 involving determining a direction of quantum mechanical influences relative to the orientation of the QFD3D device 30 using sensors oriented in orthogonal axes.

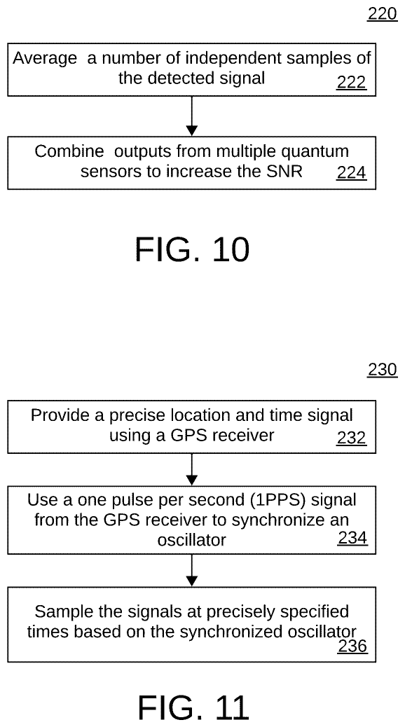

FIG. 10 illustrates a flow chart depicting logical operational steps of a method for increasing the signal-to-noise ratio (SNR) of a detected quantum mechanical influence, in accordance with an embodiment. As shown at block 222, a step or operation can be implemented to average a number of independent samples of the detected signal. Then, as depicted at block 224, a step or operation can be implemented to combine outputs from multiple quantum sensors to increase the SNR. Note, steps 222 and 224 can involve two independent methods for increasing SNR. They can be combined, but in this situation, the step or operation shown at block 224 would be implemented prior to step or operation depicted at block 222.

Regarding the ordering of the various blocks and components described herein, the functions noted in the blocks can occur out of the order noted in the figures. For example, two blocks shown in succession can, in fact, be executed substantially concurrently, or the blocks can sometimes be executed in the reverse order, depending upon the functionality involved. Iₜ can also be noted that one or more block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

FIG. 11 illustrates a flow chart depicting logical operational steps of a method 230 for synchronizing the signal sampling of potentially widely separated devices using a GPS receiver, in accordance with an embodiment. As shown at block 232, a step or operation can be implemented to provide precise location and time signal using a GPS receiver. Next, as depicted at block 234, a step or operation can be implemented to use a one pulse per second (1PPS) signal from the GPS receiver to synchronize an oscillator. Thereafter, as indicated at block 236, a step or operation can be implemented to sample the signals at precisely specified times based on the synchronized oscillator.

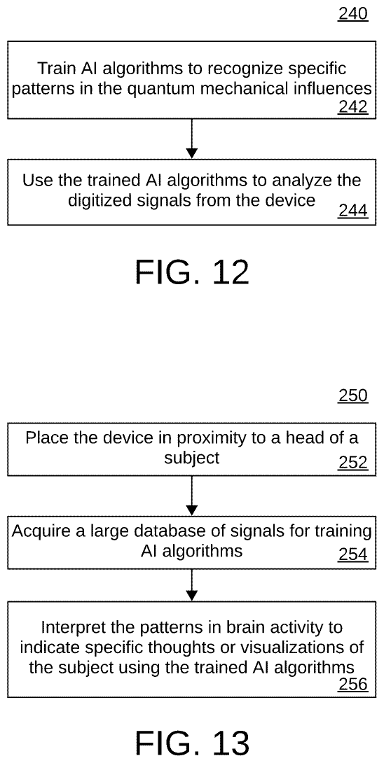

FIG. 12 illustrates a flow chart depicting logical operational steps of a method 240 for analyzing quantum mechanical influences using artificial intelligence (AI) algorithms, in accordance with an embodiment. As shown at block 242, a step or operation can be implemented to train Al algorithm(s) to recognize specific patterns in the quantum mechanical influences. Thereafter, as indicated at block 244, a step or operation can be implemented to use the trained Al algorithms to analyze the digitized signals from the QFD3D device 30.

FIG. 13 illustrates a flow chart depicting logical operational steps of a method 250 for observing patterns in brain activity using the QFD3D device 30, in accordance with an embodiment. As shown at block 252, a step or operation can be implemented to place the QFD3D device 30 in proximity to the head of a subject. Thereafter, as indicated at block 254, a step or operation can be implemented to acquire a large database of signals for training Al algorithms. Then, as depicted at block 256, a step or operation can be implemented to interpret the patterns in brain activity to indicate specific thoughts or visualizations of the subject using the trained Al algorithms.

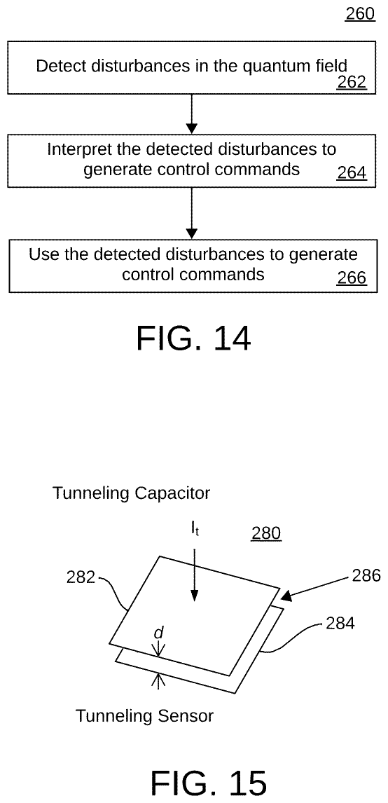

FIG. 14 illustrates a flow chart of operations depicting logical operational steps of a method 260 for detecting control signals using a QFD3D device, in accordance with an embodiment.

As indicated at block 262, a step or operation can be implemented for detecting changes in quantum field disturbances. Next, as shown at block 264, a step or operation can be implemented to interpret the detected disturbances to generate control commands. Thereafter, as illustrated at block 266, a step or operation can be implemented to use control commands to operate external devices.

FIG. 15 illustrates a tunneling capacitor, 280, which operates as a tunneling sensor to detect disturbances or variations in the quantum field in accordance with an embodiment. A metallic capacitor plate 282 and a metallic capacitor plate 284 are separated by a distance, d, wherein is situated a very thin layer of insulation or dielectric material 286, through which a tunneling current, Iₜ can flow. The insulator or dielectric material 286 is located between the capacitor plates.

Aspects of the embodiments are described herein with reference to flowchart illustrations and/or block diagrams of methods, a system or device/apparatus, and computer program products according to embodiments of the invention. Iₜ can be understood that one or more blocks of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer readable program instructions can also be stored in a computer readable storage medium that can direct a computer, a programmable data processing apparatus, and/or other devices to function in a manner, such that the computer readable storage medium having instructions stored therein comprises an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the figures illustrate an architecture, functionality, and operation of possible implementations of systems, methods, and computer program products according to various embodiments of the embodiments. In this regard, one or more blocks in the flowchart or block diagrams can represent a module, segment, or portion of instructions, which comprises one or more executable instructions for implementing the specified logical function(s).

Based on the foregoing, it can be appreciated that a number of different embodiments including preferred and alternative embodiments, are disclosed. For example, in an embodiment a device (e.g., QFD3D device 30) can be implemented for measuring classical changes due to non-classical, that is, quantum mechanical influences.

Some embodiments may also utilize sensor components alternative to those involving the use of Zener junctions. For example, FIG. 15 illustrates a schematic diagram of a tunneling sensor 280, which can be adapted for us in accordance with an alternative embodiment. The tunneling sensor 280 can be configured from a tunneling capacitor that includes, for example, capacitor plates 282 and 284 separated by a barrier, d. The tunneling sensor 280 can be implemented as an integrated planer MIM (metal-insulator-metal) capacitor that can increase leakage, which is primarily due to tunneling current, Iₜ. The barrier, d, is less than 1 μm, down to nanometers. This type of sensor can be implemented in embodiments in place of the previously discussed Zener junctions, because it is simpler, smaller and less expensive than Zener components.

An embodiment of the device is capable of determining the direction of the influences relative to the orientation of the device.

In an embodiment of the device, the non-classical influences can be detected using an array of quantum sensors.

In an embodiment of the device, the quantum sensors can be implemented as Zener diodes biased to produce shot noise.

In an embodiment of the device, the tunneling current in the Zener diodes can be modulated by quantum field disturbances.

In an embodiment of the device, the direction of the quantum mechanical influences can be determined using sensors oriented to orthogonal axes.

In an embodiment of the device, the sensors can be mounted on a printed circuit board in X, Y, and Z orientations.

In an embodiment, the device can include an amplifier or a group of amplifiers to increase the signal amplitude of the detected quantum mechanical influences.

In an embodiment, the amplifier can be a low-noise instrumentation amplifier.

In an embodiment, the device can include a low-pass filter to prevent aliasing in the digitized signal.

In an embodiment, the low-pass filter can be implemented as a 6th order Butterworth filter.

In an embodiment, the device can include an analog-to-digital converter (ADC) to digitize the detected signal.

In an embodiment, the device can include a GPS receiver to provide precise timing for signal sampling.

In an embodiment, the device can include a GPS receiver to provide a precise geographic location.

In an embodiment, the GPS receiver can provide a one pulse per second (1PPS) signal to synchronize an oscillator.

In an embodiment, the device can integrate with artificial intelligence (AI) algorithms to analyze the detected quantum mechanical influences.

In an embodiment, the Al algorithms can be trained to recognize specific patterns in the quantum mechanical influences.

In an embodiment, the device can be used in astronomical observations to detect quantum disturbances from cosmic events.

In an embodiment, the device can be oriented so the axis of one of its detectors is aligned with true north, and another detector aligned toward the zenith.

In an embodiment, the device can be used for environmental monitoring to detect quantum field variations that correlate with environmental changes.

In an embodiment, the device can be used in medical diagnostics to non-invasively detect quantum field disturbances that correlate with physiological processes.

In an embodiment, the device can be used in security and surveillance to detect unauthorized activities through their quantum field signatures.

In an embodiment, the device can be used in in developing advanced communication systems that leverage quantum field variations for transmitting and receiving information.

In an embodiment, the device is capable of being implemented in a custom integrated circuit for compact and efficient operation.

In an embodiment, the device can include multiple quantum sensors whose outputs are combined to increase signal-to-noise ratio (SNR).

In an embodiment, the device can detect patterns in brain activity by interpreting quantum field disturbances near a subject's head.

In an embodiment, the patterns in brain activity can be interpreted to indicate specific thoughts or visualizations of a subject.

In an embodiment, the device can be used for control of external or remotely-located devices based on detected quantum field disturbances.

In an embodiment, a method for measuring classical changes due to non-classical, i.e., quantum mechanical influences, can involve: detecting quantum field disturbances using an array of quantum sensors, amplifying the detected signal using a low-noise instrumentation amplifier, filtering the amplified signal using a low-pass filter to prevent aliasing, and digitizing the filtered signal using an analog-to-digital converter (ADC).

An embodiment of the aforementioned method can further involve determining the direction of the quantum mechanical influences relative to the orientation of the device by using sensors oriented into orthogonal axes.

In an embodiment, a method for increasing the signal-to-noise ratio (SNR) of a detected quantum mechanical influence can involve: averaging a number of independent samples of the detected signal and combining outputs from multiple quantum sensors to increase the SNR.

In an embodiment, a method for synchronizing the signal sampling of widely separated devices using a GPS receiver, can involve: providing a precise location and time signal using a GPS receiver, using a one pulse per second (1PPS) signal from the GPS receiver to synchronize an oscillator, and sampling the signals at precisely specified times based on the synchronized oscillator.

In an embodiment, a method for analyzing quantum mechanical influences using artificial intelligence (AI) algorithms can involve: training Al algorithms to recognize specific patterns in the quantum mechanical influences and using the trained Al algorithms to analyze the digitized signals from the device.

In an embodiment, a method for observing patterns in brain activity using the QFD3D device 30, can involve: placing the QFD3D device 30 in proximity to the subject's head, acquiring a large database of signals for training Al algorithms, interpreting the patterns in brain activity to indicate specific thoughts or visualizations of the subject using the trained Al algorithms.

In an embodiment, a method for control of external devices based on detected quantum field disturbances can involve: detecting disturbances in the quantum field, and interpreting the detected disturbances to generate control commands, and using the control commands to operate external or remotely located devices.

In an embodiment, a detector can be implemented, which can include a plurality of orthogonally oriented quantum detectors, wherein each quantum detector among the plurality orthogonally oriented quantum detectors can detect variations in the quantum field, and a signal processor that can determine a direction and magnitude of the detected quantum field variations based on outputs from the plurality of orthogonally oriented quantum detectors.

In an embodiment, each quantum detector among the plurality of orthogonally oriented quantum detectors can include an array of Zener diodes biased to produce shot noise modulated by quantum field variations.

In an embodiment, the quantum detectors among the plurality of orthogonally oriented quantum detectors can be aligned along orthogonal geographic axes, with one quantum detector aligned along a Y axis pointing true north and another quantum aligned along a Z axis pointing vertically toward a zenith.

In an embodiment, the signal processor can be configured to perform multiple measurements and apply signal averaging or other techniques to improve a signal-to-noise ratio.

In an embodiment, the detector can comprise a three-dimensional quantum field detector (QFD3D detector).

In an embodiment, a three-dimensional quantum field detector can be implemented, which can include: a first quantum detector aligned along a first axis; a second quantum detector aligned orthogonally to the first quantum detector along a second axis; a third quantum detector aligned orthogonally to the first and second quantum detectors along a third axis, wherein the first, second, and third quantum detectors are respectively aligned with a geographic X-Y-Z coordinate system such that the Y axis is oriented toward geographic true north, and the Z axis is oriented vertically toward the zenith, wherein each quantum detector comprises an array of Zener diodes biased to produce tunneling currents that generate shot noise signals; and a signal processor operable to receive and process output signals from the arrays of Zener diodes in each of the three quantum detectors, wherein variations in a quantum field modulate the tunneling current in the Zener diode arrays, and wherein the signal processor performs multiple measurements and enhances a signal-to-noise ratio to determine a magnitude and a direction of the detected quantum field variation in three-dimensional space.

In an embodiment, a method for measuring classical changes due to non-classical, i.e., quantum mechanical influences, can involve: detecting quantum field disturbances using a device comprising an array of quantum sensors; amplifying the detected signal using a low-noise instrumentation amplifier; filtering the amplified signal using a low-pass filter to prevent aliasing; and digitizing the filtered signal using an analog-to-digital converter (ADC).

An embodiment can involve determining a direction of quantum mechanical influences relative to the orientation of the device using sensors oriented to orthogonal axes.

In an embodiment, the device can be a three-dimensional quantum field detector.

In an embodiment, each quantum sensor among the array of quantum sensors can comprise a tunneling sensor.

In an embodiment, the tunneling sensor can comprise one or more tunneling capacitors.

In an embodiment, the tunneling capacitor may include a pair of capacitor plate, and a barrier having a thickness d less than 1 μm, disposed between the capacitor plates, wherein the barrier permits tunneling current variations in response to quantum field variations.

In an embodiment, the barrier thickness d may be on the order of nanometers.

In an embodiment, each tunneling capacitor can include a planar metal-insulator-metal (MIM) capacitor configured to enhance quantum tunneling-induced leakage current.

In an embodiment, each quantum sensor among the array of quantum sensors can comprise at least one Zener diode and the array of quantum sensors can comprise an array of Zener diodes.

In an embodiment, variations in a quantum field can modulate a tunneling current in the array of Zener diodes.

An embodiment can further involve performing multiple measurements and enhancing a signal-to-noise ratio to determine a magnitude and a direction of a detected quantum field variation in three-dimensional space detected by the array of quantum sensors.

Iₜ will be appreciated that variations of the above-disclosed and other features and functions, or alternatives thereof, may be desirably combined into many other different systems or applications. Iₜ will also be appreciated that various presently unforeseen or unanticipated alternatives, modifications, variations or improvements therein may be subsequently made by those skilled in the art which are also intended to be encompassed by the following claims.

What is claimed is:

1. A detector, comprising:
a plurality of orthogonally oriented quantum detectors, wherein each quantum detector among the plurality of orthogonally oriented quantum detectors detects variations in a quantum field; and
a signal processor that determines a direction and magnitude of the detected quantum field variations based on outputs from the plurality of orthogonally oriented quantum detectors.

2. The detector of claim 1, wherein each quantum detector among the plurality of orthogonally oriented quantum detectors comprises an array of Zener diodes biased to produce shot noise modulated by quantum field variations.

3. The detector of claim 1, wherein the quantum detectors among the plurality of orthogonally oriented quantum detectors are aligned along orthogonal geographic axes, with one quantum detector aligned along a Y axis pointing true north and another quantum detector aligned along a Z axis pointing vertically toward the zenith.

4. The detector of claim 1, wherein the signal processor is configured to perform multiple measurements and apply signal averaging or other techniques to improve a signal-to-noise ratio.

5. The detector of claim 1, wherein the detector comprises a three-dimensional quantum field detector (QFD3D detector).

6. The detector of claim 1, wherein each quantum detector among the plurality of orthogonally oriented quantum detectors comprises a tunneling sensor.

7. The detector of claim 6 wherein the tunneling sensor comprises at least one tunneling capacitor.

8. A three-dimensional quantum field detector, comprising:
a first quantum detector aligned along a first axis;
a second quantum detector aligned orthogonally to the first quantum detector along a second axis;
a third quantum detector aligned orthogonally to the first and second quantum detectors along a third axis, wherein the first, second, and third quantum detectors are respectively aligned with a geographic X-Y-Z coordinate system such that the Y axis is oriented toward geographic true north, and the Z axis is oriented vertically toward the zenith, wherein each quantum detector comprises an array of Zener diodes biased to produce tunneling currents that generate shot noise signals;
a signal processor configured to receive and process output signals from the arrays of Zener diodes in each of the three quantum detectors, wherein variations in a quantum field modulate the tunneling current in the Zener diode arrays, and wherein the signal processor performs multiple measurements and enhances a signal-to-noise ratio to determine a magnitude and a direction of the detected quantum field variation in three-dimensional space.

9. A method for measuring classical changes due to non-classical mechanical influences, comprising:
detecting quantum field disturbances using a device comprising an array of quantum sensors;
amplifying the detected signal using a low-noise instrumentation amplifier;
filtering the amplified signal using a low-pass filter to prevent aliasing; and
digitizing the filtered signal using an analog-to-digital converter (ADC).

10. The method of claim 9 further comprising:
determining a direction of quantum mechanical influences relative to the orientation of the device using sensors oriented to orthogonal axes.

11. The method of claim 9 wherein the device comprises a three-dimensional quantum field detector.

12. The method of claim 9 wherein each quantum sensor among the array of quantum sensors comprises a tunneling sensor.

13. The method of claim 12 wherein the tunneling sensor comprises at least one tunneling capacitor.

14. The method of claim 13 wherein the tunneling capacitor comprises:
a pair of capacitor plates; and
a barrier having a thickness d less than 1 μm, disposed between the capacitor plates, wherein the barrier permits tunneling current variations in response to quantum field variations.

15. The method of claim 13 wherein the barrier thickness d is on the order of nanometers.

16. The method of claim 13 wherein each tunneling capacitor comprises a planar metal-insulator-metal (MIM) capacitor configured to enhance quantum tunneling-induced leakage current.

17. The method of claim 9 wherein each quantum sensor among the array of quantum sensors comprises at least one Zener diode and the array of quantum sensors comprises an array of Zener diodes.

18. The method of claim 17 wherein variations in a quantum field modulate a tunneling current in the array of Zener diodes.

19. The method of claim 17 further comprising: performing multiple measurements and enhancing a signal-to-noise ratio to determine a magnitude and a direction of a detected quantum field variation in three-dimensional space detected by the array of quantum sensors.
